(19) United States
(12) Patent Application Publication
(10) Pub. No.: US 2015/0070287 A1
(43) Pub. Date: Mar. 12, 2015

(54) Touch Display and Method for Manufacturing Touch Display

(71) Applicant: Screentec Oy, Oulu (FI)

(72) Inventors: Jukka Ojala, Oulu (FI); Antti Tauriainen, Oulu (FI)

(73) Assignee: Screentec Oy, Oulu (FI)

(21) Appl. No.: 14/394,989

(22) PCT Filed: Apr. 25, 2013
(86) PCT No.: PCT/FI2013/050467

§ 371 Date: Oct. 16, 2014

(30) Foreign Application Priority Data
Apr. 26, 2012 (FI) 20125459

(51) Int. Cl. G06F 3/041; G02F 1/1333; G06F 1/16; H05K 5/03

(52) U.S. Cl. CPC G06F 3/0414; H05K 5/03; G02F 1/13338; G02F 1/133308; G06F 1/1643
USPC 345/173

(57) ABSTRACT

A touch display has, on a first surface of a frame element, at least two support members to support a touch element to be touched comprising a display unit and a protective element covering it. The touch element is connected to an electric device the control unit of which controls the image shown on the display unit. Data is supplied to the device by means of the touch element. At least two sensors for touch detection are installed on a second surface of the frame element at a position corresponding to that of the support members on the first surface of the frame element. The touch display comprises a back element for propping the sensors so that the active areas of the sensors are directed against the second surface of the frame element.

### TECHNICAL FIELD

The invention relates to a touch display and a method for manufacturing a touch display.

### RELATED PRIOR ART

A touch display identifies the location of a touch on the display unit and transmits this information to a device to which it is connected, said device then taking action according to the touch location and according to predefined instructions. A touch display detects a touch on the basis of force, pressure, change in the electrical properties or infrared radiation, for example. Touch displays are used particularly in situations in which other types of user interfaces would be impractical, bulky or susceptible to breakdown and dirt. Touch displays face challenges related to accuracy, i.e. how accurately they can determine the location of a touch, speed, i.e. how quickly they can respond to successive touches, and mechanical durability.

Touch displays may employ e.g. electromechanical film (EMF) based sensors or force sensors as their touch detection means. In EMF-based sensors, an external pressure compresses the film, which is detected as an electric current signal generated by the film. The electric current of the film is measured indirectly as a voltage signal. A change of even a few micrometres in the film thickness generates a measurable signal. The voltage signal can also be used to estimate the force exerted on the film. An EMF is disclosed in patent document FI 76225 and a keyboard based on an EMF is disclosed in patent document FI 97577.

The display unit of a touch display is electrically and mechanically connected to an electric device the control unit of which controls the information displayed on the display unit. One or more touch detection means, such as an EMF sensor or force sensor, can be attached to the housing or frame surrounding the display unit. A transparent or translucent protective element, attached to the housing of the device, is often placed on top of the sensors and display unit for their protection.

Patent application WO 2009/037383 discloses a touch screen where four EMF sensors are placed in the vicinity of the corners of a display unit, underneath a protective element. Pressure is applied, by a finger or other touching means, on a spot in the protective element. The pressure exerted on the protective element compresses the EMF sensors with forces which are proportional to the distance of the location of the touch from each of the sensors. The pressure exerted on an EMF sensor generates an electric response proportional to the pressure. A control unit reads the electric responses of the EMF sensors and, based on that, estimates the location at which pressure was exerted on the protective element and indicates this location to the electric device. The EMF sensors and control unit can also determine the force with which a spot in the protective element was touched. Based on the location or force, or both, indicated by the control unit, the electric device takes action according to pre-set instructions.

Patent documents US 2003/0214485 and US 2006/0284856 describe the use of force sensors placed on the corners of a touch screen for determining the touch location. In these, the touch location on the touch screen is determined on the basis of signals coming from the different sensors.

FIGS. 1a and 1b show a touch display structure according to the prior art in a sectional side view. Omitted from the figure is the device to which the touch display is connected, and omitted are also the electric wires and control unit. The display unit 103 and the protective element 101 thereon may touch one another or be slightly detached from one another. The display unit 103 is surrounded by a housing structure 105 which shields and supports the display unit 103. The sensors 102, 104 are placed in between the protective element 101 and the frame or housing structure 105 surrounding the display unit 103. The protective element 101 may be provided with a separate support surface 107 at the active areas of the sensors 102, 104. Similar support surfaces 107 can be provided on those surfaces of the sensors 102, 104 which face the protective element 101.

For clarity of illustration, the support surface 107 and the upper surface of sensor 104 are drawn separately in FIG. 1 b. In normal operation, the support surface 107 in connection with the protective element 101 touches the upper surface of sensor 104. On the surface of sensor 104 there may be a raised area (not shown) formed e.g. by a protrusion in the sensor or other irregularity on the surface of the sensor 104 facing the protective element 101. For clarity of illustration, the sizes of the sensors 102, 104 and support surfaces 107 are exaggerated in FIGS. 1a and 1b.

The support surfaces 107 are formed such that the active areas of the sensors 102, 104 are aligned with the support surfaces 107. The support surfaces 107 can be attached to the surface of the protective element 101 or sensors 102, 104 with a thin elastic layer of adhesive. The purpose of the support surfaces 107 is, on the one hand, to shield the protective element 101 against dents caused e.g. by the structure, operation or movement of the sensors 102, 104 and, on the other hand, to yield under actions, such as presses, applied onto the protective element 101 so that the information about a press is conveyed to the active areas of the sensors 102, 104.

If the touch display is implemented using EMF sensors, the support surfaces should be mechanically very durable so that the performance and accuracy of the film-based sensors, which are very sensitive to touch, will not suffer. The support structures and surfaces built should not be susceptible to breakdown.

Compared to EMF sensors, force sensors are more expensive and take up more space in the equipment housing, which is significant in the case of portable communications devices, for example. Force sensors may have protrusions on their surfaces, which imposes challenges for their use in touch displays. Force sensors are particularly susceptible to breakdown, which is why they must be shielded with support structures and surfaces. The support structures and surfaces built must have excellent durability.

In the prior art solutions, support structures and/or surfaces need to be constructed between the sensors and the protective element, at sensor surfaces facing the protective element, and the material of these support structures and/or surfaces has to be hard enough to convey the touch information from the protective element to the sensor as reliably as possible and, on the other hand, elastic enough to prevent damage to the protective element caused e.g. by potential bumps or other uneven spots on the sensor surface when the screen is touched. This makes it more difficult to mount the touch display's sensors and display unit and in particular its protective element.

Support structures or support surfaces like those mentioned above can be made e.g. from silicone and polyethylene terephthalate (PET) films.

Unfortunately, support structures between the sensors and protective element made of silicone and PET films or other known materials with similar properties break easily and, therefore, the touch displays are unreliable and failure-prone. Furthermore, the sensors are susceptible to detrimental environmental effects.

In the prior art touch displays, the replacement of failed sensors is a difficult multi-step operation, if it can be carried out at all. The sensors have to be replaced by a skilled person who first needs to remove the protective element and then the sensor with its wiring attached thereto by means of the support structure. In most cases, the installation of a new sensor also requires that a new support structure be constructed between the sensor and protective glass.

### SUMMARY OF INVENTION

An object of the invention is to provide a novel touch display which significantly mitigates the drawbacks and disadvantages associated with the prior art.

The objects of the invention are achieved through a touch display characterised in that which is disclosed in the independent claim 1 and through a method characterised in that which is disclosed in the independent claim 10. Advantageous embodiments of the invention are presented in the dependent claims.

A touch display according to the invention comprises a frame element with at least two support members on a first surface thereof. The touch display comprises a touch element supported by the support members, the touch element covering the outer support surfaces of the support members. The touch element is advantageously placed on top of the support members so that the outer support surfaces of the support members are covered by the touch element. For detecting a touch, the touch display comprises at least two sensors on a second surface of the frame element at a position corresponding to that of the support members on the first surface of the frame element. The touch display further comprises a back element to prop the sensors so that the sensors' active areas are placed against the second surface of the frame element. The back element props the sensors so that their normal operation for detecting a touch takes place in an optimal manner when the touch element is touched by a finger or other pointing means whereby a pressure is applied onto the touch element.

According to an advantageous embodiment, the outer surfaces of the support members in the touch display are at a level higher than that of the first surface of the surrounding frame element. In one example, the outermost surfaces of the support members are at a level which is 0.5 mm higher than the level of the first surface of the frame element. The touch element is advantageously mounted on top of the outer surfaces of the support members. A touch-induced force or pressure on the touch element is conveyed by the support members to the sensors placed on the second surface of the frame element at a position corresponding to that of the support members on the first surface of the frame element. It is also possible, but not absolutely necessary, to create, advantageously through working or moulding, thinnings on the first surface of the frame element around the support members so that, at a thinning, the frame element is thinner around the support member than elsewhere on the first surface of the frame element. In one example, the thickness of the frame element at a thinning around a support member is advantageously 0.2 to 1.0 mm.

According to an advantageous embodiment, the active areas of the sensors for detecting a touch are located at a position of the second surface of the frame element which position corresponds to that of the support members on the first surface of the frame element. The force or pressure applied to the touch element is then conveyed through the support members to the active areas of the sensors. The active area of a sensor means that physical spot or area in or on a sensor or a part or component protruding outward from the sensor which primarily senses (detects) the touch-induced force or pressure on the touch element whereby, as a result of the detection, the sensor generates an electric response. For example, in an EMF sensor the active area is an area sensitive to the compression of a film facing the touch element. In this case, the back element props the second film of the film-based sensor so that it stays in its place. For example, in a capacitive force sensor the active area consists of a protruding part of a conductive strip extending from the surface of the sensor in the direction of the touch element so that a pressure or force presses the protruding part against a second conductive part underneath it. The back element props the second conductive part so as to prevent it (and the rest of the force sensor with the exception of its active areas) from moving.

According to an advantageous embodiment, the second surface of the frame element in the touch display comprises a hollow against which the sensor is propped up by means of the back element so as to enable the normal operation of the sensor in order to detect a touch directed to the touch element. The hollow is advantageously produced by working or moulding the second surface of the frame element into a hollow shape, wherein the dimensions of the hollow are such that the sensor fits into it in a manner that allows its normal operation. The sensor should fit into the hollow so that the active touch-detecting areas of the sensor are placed against the second surface of the frame element at a position corresponding to that of the corresponding support member on the first surface of the frame element. The sensor is anchored in the hollow against the second surface of the frame element by means of the back element which is advantageously a back plate or board made of a rigid material or an epoxy layer. The back element may be e.g. a printed circuit board to which the sensor is connected electrically and mechanically. The sensor can be attached advantageously by means of an adhesive e.g. onto the second surface of the frame element or to a desired position in the hollow or onto the back element.

In an advantageous embodiment of a touch display according to the invention, the touch element comprises a display unit covered with a protective element. In another advantageous embodiment, the touch element comprises a protective element supported by support members on the first surface of the frame element, and a display unit which touches it or is to an extent detached from it and is surrounded by the frame element. In that case the protective element has a larger area than the display unit. Advantageously, the protective element of the touch element rests on the outer surfaces of the support members and the protective element covers the display unit which is smaller in area than the protective element. In another advantageous embodiment the touch element is a liquid crystal display. The protective element may be a glass plate or similar or a film which is translucent or transparent. The material of the protective element is chosen so as to be durable and easy to clean. The materials and properties of the protective element should be such that the touch-induced pressure directed thereto will be accurately conveyed onwards from the protective element.

According to an advantageous embodiment, the touch display has four support members located on the first surface of the frame element such that they support the touch element, which rests on them, near the corners of the touch element. Similarly, advantageously four sensors are located on the second surface of the frame element at positions corresponding to those of the four support members. Advantageously, the first and second surfaces are surfaces on the opposite sides of the frame element.

A portable or otherwise movable or fixed electric device according to the invention comprises at least a touch display according to any of the advantageous embodiments of the invention.

A method according to the invention for manufacturing a touch display comprises a step of providing at least two support members on a first surface of a frame element such that the outer surfaces of the support members remain elevated from the level of the first surface. The method further comprises a step of providing locations for sensors on the second surface of the frame element at positions which correspond to those of the support members on the first surface of the frame element. In one step of the method, the sensors are placed in the locations so that the active touch-detecting areas of the sensors face the second surface of the frame element at positions corresponding to those of the support members. The method further comprises a step of placing a rigid back element at positions corresponding to those of the sensors so that the back element holds the sensors in their places with the sensors' active areas facing the second surface of the frame element. The method further comprises a step of mounting a touch element on top of the outer surfaces of the support members. The above steps of the method may be carried out in an order other than that described above.

In some embodiments of the method the frame element is made of metal, light metal, steel, plastic or other such durable material so that the frame element can be worked as desired or moulded into shapes as desired.

In an embodiment of the method the sensors are installed in their locations and attached to the frame element advantageously by means of an adhesive. In another embodiment of the method the sensors are installed in their locations such that the sensors are electrically and mechanically connected with the back element. The sensors can be assembled e.g. on PET films or other plastic films or on printed circuit boards (PCB) or Flex-PCBs with the electric connections built such that the electric responses of each sensor can be conveyed in a centralised manner to the control unit of the touch display, for example.

A touch display according to the invention can be used instead of or in addition to a traditional keyboard or keypad in various electric devices. An implementation of the invention, which enables the production of small, lightweight and durable touch displays, is applicable in portable devices, such as telephones, palmtop computers, laptop computers, portable music players and gaming devices, for instance. A touch display according to the invention can also be used in large displays.

An advantage of the invention is that the sensor can be installed behind the mechanical structure, thereby significantly improving the durability and reliability of the sensor and the touch display itself. At the same time, the sensors become less sensitive to environmental effects, such as moisture, heat, radiation, and such. As the sensors are delicate components and critical for the functioning of the touch display it is of utmost importance that they should be stable and reliable in their operation. The advantages mentioned above may be improved even further when the sensors are placed on the lower surface of the frame structure in hollows or holes worked or moulded specially for the purpose. The sensor is then surrounded and protected by a mechanical structure on all sides. The durability of the touch display is also improved by the fact that in a touch display according to the invention the sensors are installed on a different side of the frame element than the touch element and there is thus no need to build any special fastening structures between the sensor and touch element e.g. from silicone and PET films which break easily in use.

Another advantage of the invention is that the touch display will be easier to make and repair as the sensors and touch element can be installed in separate work phases during the assembly of the touch display. This is possible because, as mentioned above, there is no need to build any special fastening structures between the sensor and touch element. The sensors can be replaced by removing the back element and the sensors behind it. Similarly, the touch element or the protective element can be replaced without touching the sensors.

A further advantage of the invention is that fewer components are needed to make the touch display as the support members according to the invention are advantageously part of the frame element or can be formed in the frame element.

A still further advantage of the invention is that it can be used to provide a small touch display applicable in portable electric devices.

### BRIEF DESCRIPTION OF THE DRAWINGS

The invention is below described in detail. In the description, reference is made to the accompanying drawings in which

FIGS. 1a and 1 b show a side view of the prior art touch display,

FIG. 2 shows, as an example, a side view of an advantageous embodiment of the invention,

FIG. 3 shows, as an example, a side view of another advantageous embodiment of the invention,

FIG. 4 shows, as an example, a flow diagram of an embodiment of a method according to the invention,

FIG. 5 shows, as an example, details of an advantageous embodiment of the invention as seen from above, and

FIG. 6 shows, as an example, details of an advantageous embodiment of the invention as seen from above.

### DETAILED DESCRIPTION OF INVENTION

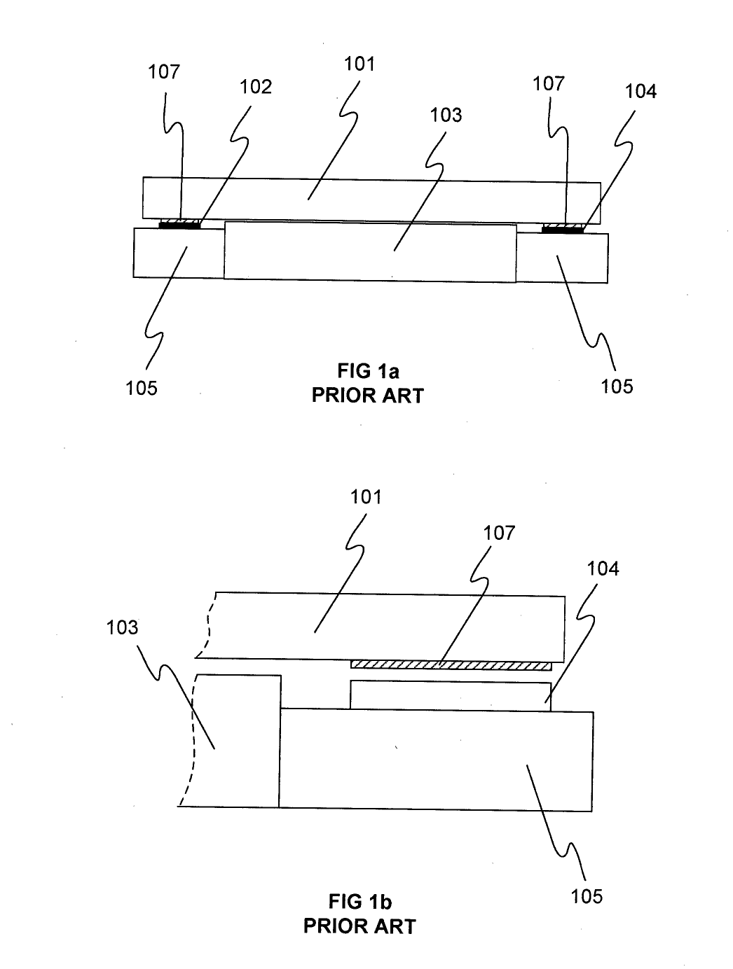

FIGS. 1a and 1b were discussed above in connection with the description of the prior art.

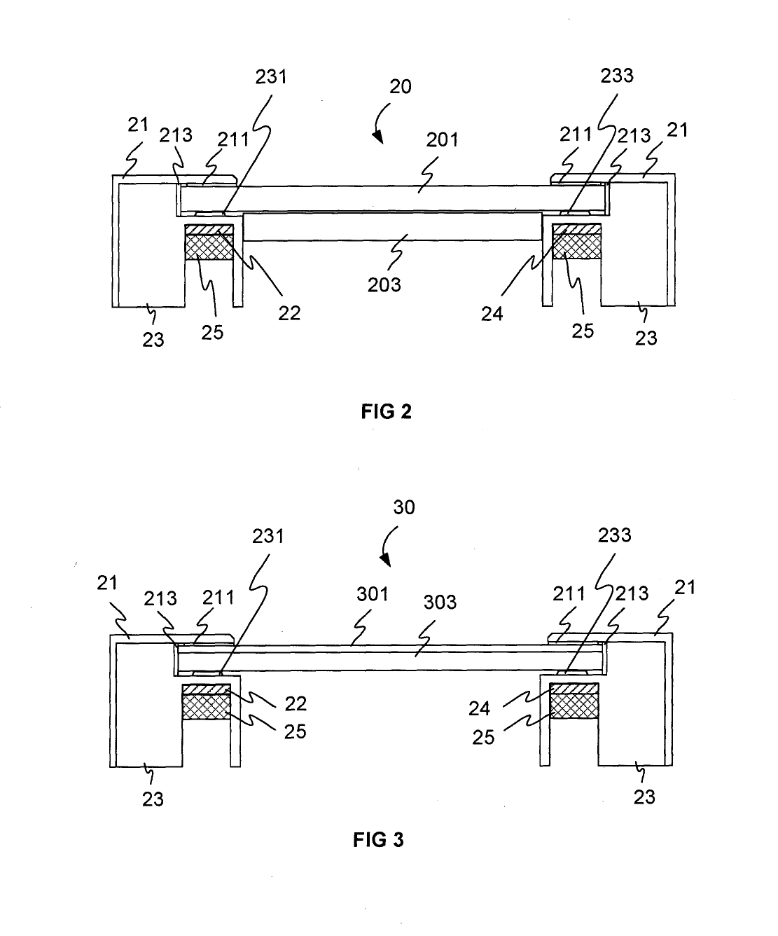

FIG. 2 shows, as an example, a side view of an advantageous embodiment of a touch display according to the invention. The touch element 20 comprises a display unit 203 and a protective element 201 which covers it. A frame element 23 in the touch display is adapted to support the touch element 20 such that the protective element 201 is supported by the support members 231, 233 on a surface of the frame element 23. The support members 231, 233 may also be called pads. The frame element 23 surrounds and at the same time protects and supports the display unit 203.

The display unit 203 may be e.g. the display of a cellular telephone, display of a palmtop computer, display of any of varied automata or the display of a PC. The display unit 203 gets its operating power and the data needed for the display of an image or similar visual information from an external electric device to which it is attached and connected. The electric device may be a portable or otherwise movable device or a fixed-mounted device. Omitted from the figure is the electric device to which the touch display is connected, and omitted are also the electric connecting means and the control unit.

The protective element 201 is placed on top of the display unit 203. The placement is carried out such that the protective element 201 touches the display unit 203 or is slightly detached from it. The protective element 201, too, can be surrounded by the frame element 23. The protective element 201 can also be placed such that its edges touch the frame element 23 surrounding the display unit 203. The protective element 201 can be attached by its edges to the frame element 23 by means of an attaching means 213. Similarly, the display unit 203 covered by the protective element 201 can be attached by its edges to the frame element 23. The touch element 20, which comprises the protective element 201 and display unit 203, can also be encased e.g. in the housing 21 of the electric device, in which case the gap between the protective element 201 and housing 21 can be sealed using a sealant 211 which protects the device and the touch element 20.

According to FIG. 2, the protective element 201 belonging to the touch element 20 is placed on the support members 231, 233 on a surface of the frame element 23. Advantageously there are four support members 231, 233 and they are placed on the upper surface of the frame element 23 such that each of the support members 231, 233 is placed near a corner of the protective element 201 and is covered by the protective element 201. The support members 231, 233 are produced on a surface of the frame element 23 e.g. by mechanical working or in a moulding process where they are moulded as part of the surface of the frame element 23. The support members 231, 233 may also be achieved by attaching separate support members to a surface of the frame element 23. As the touch element 20 is intended to rest on the support members 231, 233, the outer surfaces of the support members 231, 233, on which the touch element 20 is placed, are worked or moulded somewhat higher than the rest of the upper surface area of the frame element 23. In one example, the outer surfaces of the support members 231, 233 are at a level which is 0.5 mm higher than the rest of the upper surface of the frame element 23 on average.

The sizes of the support members 231, 233 depend on the sensor size in a manner described later on. The pressure or force caused by a touch directed to the protective element 201 belonging to the touch element 20 supported by the support members 231, 233 is to be conveyed onwards by the latter. The conveying properties of the support members 231, 233 can be improved by thinnings formed around them in the frame element 23 by working, moulding or otherwise, wherein the frame element 23 is thinner than in areas outside the thinnings. In one example, the thickness of the frame element at a thinning around a support member 231, 233 is advantageously 0.2 to 1.0 mm.

In the frame element 23, the support members 231, 233 are positioned on the surface against which the touch element 20 or the protective element 201 belonging to it is installed. Sensors 22, 24 are placed on that side of the frame element 23 which is opposite to the above-mentioned surface, at a position corresponding to the support members 231, 233 so that the active touch-detecting areas of the sensors 22, 24 are placed closest to the support members 231, 233. Advantageously, the active areas of the sensors 22, 24 and the support members 231, 233 are at mutually corresponding positions on opposing surfaces of the frame element 23. Then the force or pressure applied to the protective element 201, which belongs to the touch element 20, is conveyed through the support members 231, 233 to the active areas of the sensors. The active area means that physical spot or area in or on a sensor or a part or component of a sensor which e.g. protrudes outwards therefrom which primarily senses (detects) the touch-induced force or pressure on the touch element whereby, as a result of the detection, the sensor 22, 24 generates an electric response.

The terms upper surface and lower surface of the frame element used e.g. in connection with FIG. 2 are only meant to describe that the upper and lower surfaces are surfaces on the opposite sides of the frame element. These terms do not necessarily mean that one surface is above or beneath the other.

By suitably shaping the frame element 23, e.g. through working or moulding, hollows are produced on the lower surface of the frame element 23 where the sensors 22, 24 can be located. When the dimensions of the hollows correspond to the size of the sensors, the hollows effectively protect the sensors against environmental harms. The sensors 22, 24 should fit into the hollows so that the active touch-detecting areas of a sensor 22, 24 are placed against a surface of the frame element 23 at a position corresponding to that of the corresponding support members 231, 233 on the opposite surface of the frame element 23. The hollows may be e.g. holes with one sensor placed in each. A hollow may also be realised as a continuous groove which goes around the entire frame element 23 through locations defined by the support members 231, 233 but on a side of the frame element 23 opposite to which the support members 231, 233 are located on.

The sensors 22, 24 are anchored in their places by a back element 25 such that the active areas of the sensors 22, 24 are directed against the second surface of the frame element 23. The back element 25 is attached to the frame element 23, for example. When the sensors 22, 24 are installed in the hollows, they are held in their places by a back element 25 such that the active areas of the sensors 22, 24 are directed against the lower surface of the frame element 23. If, for example, EMF sensors are used as sensors 22, 24, the back element 25 should be rigid enough to allow the EMF sensor to be compressed against it when the touch element 20, 30 is touched. If, for example, capacitive force sensors are used as sensors 22, 24, the back element 25 should be rigid enough to hold the force sensor in its place when the touch element 20, 30 is touched.

The back element 25 is advantageously a back plate or board made of a rigid material or an epoxy layer. Suitable materials include e.g. metal, plastic or other rigid material. Epoxy is used to reinforce e.g. a plastic film onto which the sensors 22, 24 are assembled such that they can be mechanically and electrically connected as part of the touch display. The sensors may be assembled on a PET or other plastic film, for example. The back element 25 may also be e.g. a printed circuit board to which the sensor or sensors 22, 24 are connected electrically and mechanically. The sensors may be assembled on a PCB or Flex-PCB, for example. The electric connection means of sensors 22, 24 assembled on films, PCBs or other circuit boards can be connected in a centralised manner to the control unit of the touch display using suitable connectors. The sensors 22, 24 can be attached advantageously by means of an adhesive e.g. onto the second surface of the frame element or to a desired position in the hollow or onto the back element 25.

FIG. 3 shows, as an example, a side view of another advantageous embodiment of a touch display according to the invention. A touch element 30 comprises a display unit 303 and a protective element 301 which covers it. A frame element 23 in the touch display is adapted to support the touch element 30 such that the display unit 303 is supported by support members 231, 233 on a surface of the frame element 23. The frame element 23 surrounds and at the same time protects and supports the display unit 303 and the protective element 301 which covers it. The touch element 30 may be attached by its edges, using a means of attachment 213, such as e.g. silicone, to the surrounding frame element 23. The touch element 30 may also be encased in the housing 21 of the electric device, in which case the gap between the protective element 301 and housing 21 can be sealed using a sealant 211 which protects the device and the touch element 30. The display unit 303 in the touch element 30 functions in the same way as the display unit 203 in the touch element 20 of FIG. 2. There is, however, a difference which is that the material and properties of the touch display 303 of the touch element 30 should enable the latter to convey a pressure or force caused by a touch directed to the protective element 301 to the support members 231, 233. In all other respects the embodiment of FIG. 3 is similar to that which was described in connection with FIG. 2.

When a force or pressure is directed through a touch to a location on the protective element 201, 301, a force applies to each of the sensors 22, 24 which force is slightly different for each sensor depending on the distance between the touch location on the protective element 201, 301 and each particular sensor. Compression causes each of the sensors 22, 24 to generate an electric response, such as e.g. a voltage signal, which can be transferred through transfer means to a control unit for identification and analysis. The operating mechanisms of sensors used in touch displays are described in more detail e.g. in patent application FI 20105412 or patent publication US 2003/0214485.

The protective element 201, 301 is entirely or partly made of transparent or translucent material so that an image or light can be seen on the display unit 203, 303 beneath it. The material of the protective element 201, 301 is also chosen so as to be durable and easy to clean. The protective element 201, 301 may be shaped or coloured so that e.g. keys or symbols can be produced on the protective element 201, 301. The display unit 203, 303 beneath the protective element 201, 301 can illuminate the symbols on the protective element using different colours.

In one example, the display unit 203, 303 in the touch element 20, 30 is a liquid crystal display.

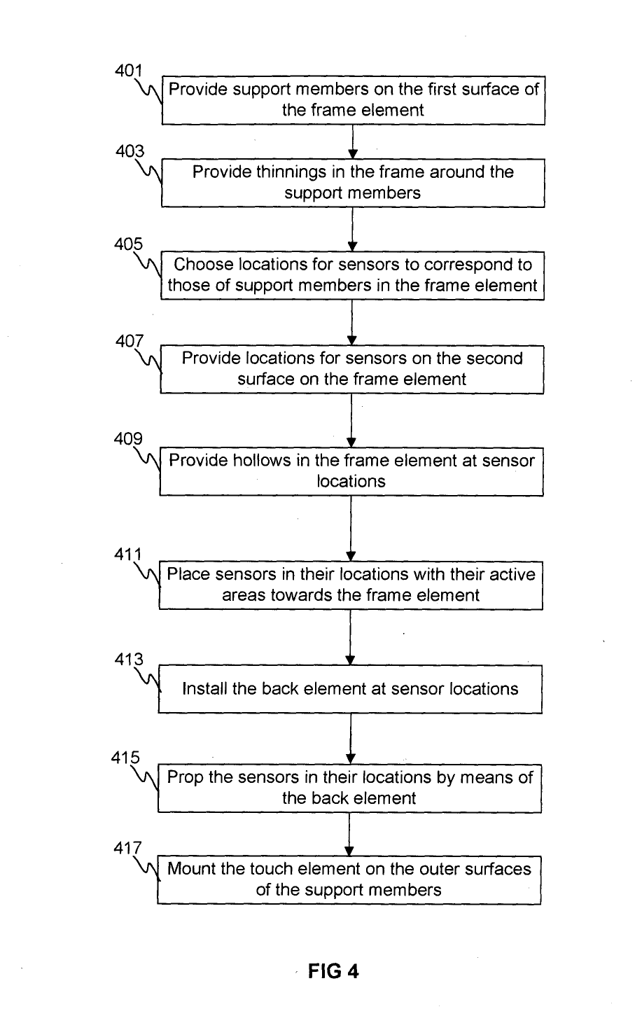

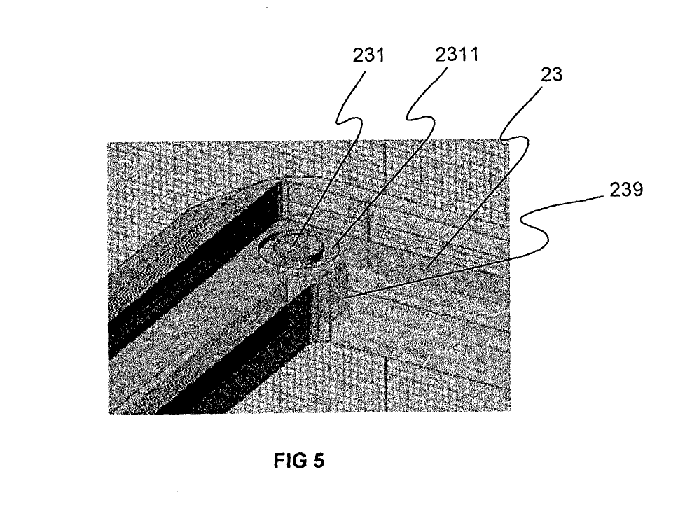

FIG. 4 shows as an example a flow diagram of an embodiment of the method according to the invention for manufacturing a touch display. The method for manufacturing a touch display comprises the following steps, for instance. In step 401, support members are produced, e.g. by working mechanically or moulding, on a first surface of the frame element. The material of the frame element may be e.g. a light metal, steel, plastic or other material suitable for the mechanical structure. The outer surfaces of the support members are left taller than the average surface of the frame element in the surface area where the support members are located. The next step 403 is optional. In step 403, thinnings are produced in the frame element around the support members. FIG. 5 shows as an example a support member 231 and a thinning 2311 produced around it in the frame element 23. The thinnings 2311 are produced e.g. by removing material from a desired area around the support members 231, 233 or by forming them in the moulding process for the frame element 23. In step 405, the locations for the sensors are chosen on that side of the frame element which is opposite to the one where the support members are located so that the sensor locations on the second surface correspond to the locations of the corresponding support members on the first surface of the frame element. In step 407, locations for sensors are provided, e.g. by means of working mechanically or moulding, on the second surface of the frame element at positions which correspond to those of the support members on the first surface of the frame element. In step 409, hollows are provided, e.g. by means of working or moulding, on the second surface of the frame element at the sensor locations. FIG. 5 illustrates an example of an outer wall of a hollow 239 below a support member 231. FIGS. 2 and 3 show other examples of hollows (no reference number) where the sensors 22, 24 are located in such a hollow. The hollow may also comprise a continuous groove going around the edges. In step 411, the sensors are placed in the locations so that the active touch-detecting areas of the sensors face the second surface of the frame element at positions corresponding to those of the support members. In step 413, a rigid back element is placed at locations of the sensors on the sensor side of the frame element. If the sensors are located in hollows, the back elements are placed at the hollows so that the sensors are left between the back elements and the second surface of the frame element. If the hollow is realised as a continuous groove, a single continuous back element may also be used. The back element 25 may be a mechanical board or it can be produced by providing a layer of epoxy on a film, for example. In step 415, the sensors are anchored to their places by back element(s) so that the sensors' active areas are placed against the second surface of the frame element. In step 417, a touch element is mounted on the outer surfaces of the support members. Step 417 may also be carried out right after step 401 or step 403 with the support members already provided. The steps listed above can be carried out in an order different from the one described above, if desired.

The number and location of sensors and support members can vary in different applications.

Advantageous embodiments of the device according to the invention were described above. The invention is not limited to the solutions described but the inventional idea can be applied in many different ways within the scope defined by the claims.

1. A touch display comprising
a frame element having, on opposing sides thereof, a first surface and a second surface such that the frame element is partially between said surfaces,
at least two support members on the first surface of the frame element,
a touch element to be touched supported by the support members, the touch element covering the outer support surfaces of the support members,
at least two sensors for touch detection on the second surface of the frame element at a position corresponding to that of the support members on the first surface of the frame element, and
a back element for propping the sensors against the second surface of the frame element so that, when the touch element is touched, the force or pressure directed to the support members is adapted to be conveyed to the sensors.

2. A touch display according to claim 1, wherein touch-detecting active areas of the sensors are located against the second surface of the frame element at a position corresponding to that of the support members on the first surface of the frame element so that a force or pressure directed to the touch element is conveyed from the support members through a portion of the frame element to the active areas of the sensors.

3. A touch display according to claim 1, wherein the second surface of the frame element comprises a hollow against which the sensor is propped by a back element.

4. A touch display according to claim 1, wherein the outer surfaces of the support members are higher than the first surface of the surrounding frame element.

5. A touch display according to claim 1, which further comprises a transfer means and control unit, wherein the transfer means is arranged to transfer to the control unit electric responses caused in the sensors by a pressure directed to the touch element and wherein, on the basis of the electric responses received, the control unit is arranged to identify the location on the touch element to which the touch-induced pressure was directed or the force with which the touch element was touched or both said location and said force.

6. A touch display according to claim 1, wherein the touch element comprises a display unit covered by a protective element.

7. A touch display according to claim 1, wherein the touch element comprises a liquid crystal display.

8. A touch display according to claim 1, wherein the touch element comprises a protective element supported by said support members and a display unit which touches the protective element or is detached from it and is surrounded by the frame element.

9. A portable electric device comprising at least a touch display comprising:
a frame element having, on opposing sides thereof, a first surface and a second surface such that the frame element is partially between said surfaces,
at least two support members on the first surface of the frame element,
a touch element to be touched supported by the support members, the touch element covering the outer support surfaces of the support members,
at least two sensors for touch detection on the second surface of the frame element at a position corresponding to that of the support members on the first surface of the frame element, and
a back element for propping the sensors against the second surface of the frame element so that, when the touch element is touched, the three or pressure directed to the support members is adapted to be conveyed to the sensors.

10. A method for manufacturing a touch display comprising
providing a frame element having, on opposing sides thereof, a first surface and a second surface such that the frame element is partially between said surfaces,
providing at least two support members on the first surface of the frame element,
providing locations for sensors on the second surface of the frame element at positions corresponding to those of the support members on the first surface of the frame element,
placing the sensors in said locations so that the active touch-detecting areas of the sensors face the second surface of the frame element at positions corresponding to those of the support members,
placing a back element at the locations of the sensors wherein the back element anchors the sensors to their locations so that the active areas of the sensors are directed against the second surface of the frame element, and
mounting a touch element on the outer surfaces of the support members so that, when the touch element is touched, the force or pressure directed to the support members is conveyed to the sensors.

11. A method according to claim 10, wherein thinnings are produced around the support members by molding, or thinnings are produced around the support members by removing a necessary amount of material from the frame element.

12. A method according to claim 11, wherein the thickness of the frame element at the thinning around the support members is 0.2 to 1 mm.

13. A method according to claim 10, wherein the outer surfaces of the support members remain elevated from the level of the first surface of the frame element.

14. A method according to claim 10, wherein the frame element is made of metal, light metal, steel or plastic.

15. A method according to claim 10, wherein hollows are worked or molded on the second surface of the frame element as locations for the sensors.

16. A method according to claim 10, wherein the sensors are mounted in their locations and attached to the frame element advantageously by means of an adhesive.

17. A method according to claim 10, wherein the sensors are mounted in their locations so that the sensors are electrically and mechanically connected to the back element.

18. A method according to claim 10, wherein the back element is a mechanical back board, printed circuit board, plastic board or an epoxy layer to prop the sensor so as to enable its normal operation.

19. A method according to claim 10, wherein the touch element is attached to the surrounding frame element advantageously by means of silicone.

20. A method according to claim 10, wherein the method further comprises
providing the protective element and the display unit which touches it or is detached from it to form the touch element,
supporting the protective element by the support members, and
surrounding the touch element by the frame element.

21. A method according to claim 10, wherein the method further comprises covering the display unit by the protective element to form the touch element,
supporting the touch element by the support member, and
surrounding the touch element by the frame element.
